(19) United States
(12) Patent Application Publication
(10) Pub. No.: US 2014/0318594 A1
(43) Pub. Date: Oct. 30, 2014

(54) Detachable Photovoltaic Module with Tab

(71) Applicant: Bruce Allen, Santa Barbara, CA (US)

(72) Inventor: Bruce Allen, Santa Barbara, CA (US)

(21) Appl. No.: 13/936,162

(22) Filed: Jul. 6, 2013

Related U.S. Application Data
(60) Provisional application No. 61/816,137, filed on Apr. 25, 2013.

(51) Int. Cl. H01L 31/042; H01L 31/05

(52) U.S. Cl. CPC H01L 31/0422; H01L 31/0504
USPC 136/244; 136/252; 136/256

(57) ABSTRACT

A detachable and/or repositionable photovoltaic module for providing a solar powered electrical energy source. The module is preferably provided with a chemical semi-adhesive coating on its non-active backside which allows it to be attached to a variety of surfaces, such as tablets, cell phones, or automobile roofs in a manner that easily supports removal and re-installation. The module may be plugged into these devices as a power source. The module also is preferably provided with one or more lifting elements such as an extended tab, or extrusion of a portion of the module. The Module and lifting elements combination may also employ other semi-adhesives such as Velcro or magnets.

### RELATED APPLICATIONS

This application claims priority to U.S. Provisional Application Ser. No. 61/816,137 filed Apr. 25, 2013

### FEDERALLY SPONSORED RESEARCH

Not Applicable

### SEQUENCE LISTING

Not Applicable

### BACKGROUND OF THE INVENTION

This application relates to detachable and repositionable photovoltaic modules used as easily installable, removable and reusable solar powered electric energy sources.

Photovoltaic (PV) materials and modules are becoming thinner and lighter and more efficient and thus more suitable for providing solar powered compact energy sources for a wide range of devices, such as personal electronics, ie tablets, cell phones etc. as well as larger scale applications such as automobiles.

There is a need for photovoltaic cells and modules to be attached semi-permanently to surfaces, devices, objects and structures for a period of time but be easily removable and re-attachable to a different surface or back to the original surface. This increases the flexibility, utility and value of PV modules. The ability to easily remove a PV module from a surface, device, or object to which the PV supplies electricity allows the re-use of the PV module, or the use of one module attachable to a device currently in use, and then removed and attached to the next device used.

As PV materials become thinner and more efficient, PV materials increasingly will find use in an expanding array of consumer devices and other applications that benefit from PV modules providing electricity. The ability to attach, detach and re-attach a PV module to more than one surface increases the value of a PV module, reduces the cost to the user and increases the utility of a PV module.

### BRIEF SUMMARY OF THE INVENTION

The invention is a novel configuration for photovoltaic modules, including one or more PV cells, preferably of a type configured to generate electrical energy when exposed to light. PV modules are known in the art and generally either produced with wafer based semiconductor fabrication or also may be printed using thin film device fabrication techniques. In either case, the active PV devices are attached to a substrate such as glass for the wafer produced devices or printed onto a backsheet for the thin film devices. Thus the PV module usually consists of an active surface with PV devices, often covered with a clear protective sheet, and an opposite backing surface. For both types of processing, the modules are becoming very thin and in many cases flexible enough to conform to moderately curved surfaces such as cell phones or tablets. The degree of flexibility and thinness for any given type of module is known in the art and several types are suitable for the current invention.

The invention is such a module which includes a chemical semi-adhesive covering at least a portion of the backing surface. This adhesive is chosen to allow for attachment of the module to a surface semi-permanently but capable of at least two and preferably many cycles of removing and re-installing the module on surfaces.

The novel PV module also includes at least one electrical connector and at least one lifting element for ease of removing operations. In a particular embodiment, the lifting element is a tab, which may be flexible, rigid and/or flexibly attached, extending out from an edge of the module. The tabs may be composed of a wide variety of materials including plastics, cloth, metal, composite material or other suitable materials. The tab may have a variety of implementations. It may optionally also include semi-adhesive for securing to the mounting surface. The tab and the electrical connector may be one unit. The tab may be hinged to rotate from a stored to a deployed position. The tab may also be a part of the module, such as exposed backing for example, extending out from the active area and shaped/sized for convenient handling. It can be a protected active region of the module as well, suitably shaped for convenient lifting actions. The lifting element may also be a raised or beveled edge of the module.

The chemical semi-adhesive may take several forms, including a spray coating, a liquid coating, a powder coating or a double sided tape. It may be advantageous to use adhesives of differing properties on the module backside and the lifting element. The adhesive may also be provided with a cover sheet, removed for installation. Some adhesives may be renewable by re-application or other means. Some adhesives may also be heat activated either for installation or removing.

The combination of the module and lifting tab may also be used with non-chemical semi-adhesives such as, for example, magnets or Velcro.

### BRIEF DESCRIPTION OF THE DRAWINGS

The invention will be better understood by referring to the following figures.

FIG. 1 depicts the basic elements of the invention where the lifting element is an extended tab and the electrical connection is by way of cable with connector.

FIG. 2 depicts an alternative embodiment where the lifting element is a raised edge of the module.

FIG. 3 depicts an embodiment where the electrical connection is by way of integral connector.

FIG. 4 depicts an embodiment where the lifting element and electrical connector are formed into one piece

FIG. 5 depicts an embodiment where the lifting element is hinged.

### DETAILED DESCRIPTION OF THE INVENTION

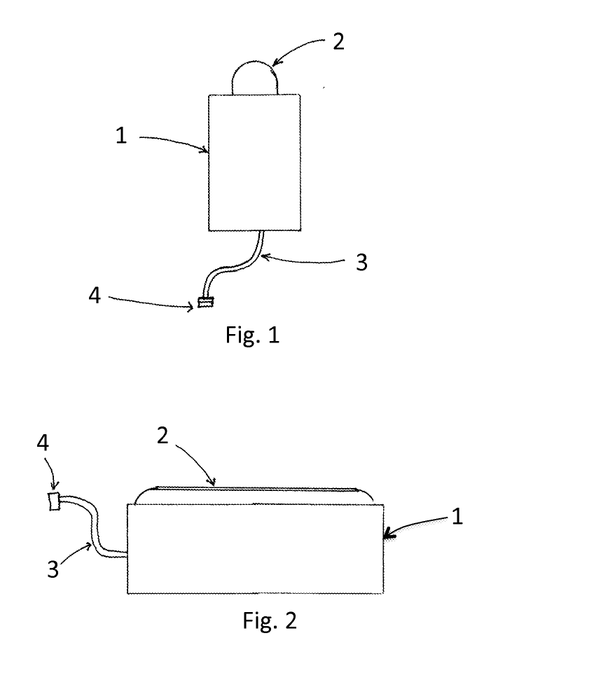

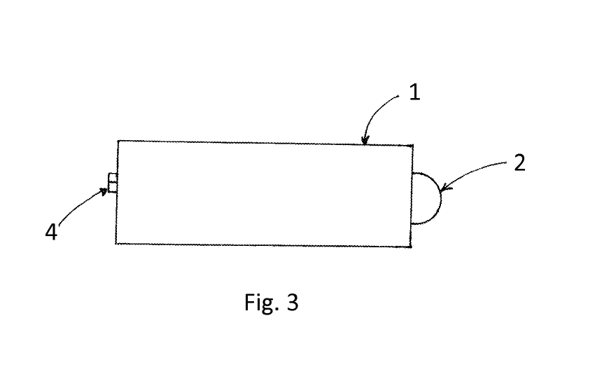

Referring to FIG. 1, the various elements of the invention are shown. Photovoltaic module 1 is of a type having one or more photovoltaic devices on one side and a photovoltaic module backing material on the other. Suitable known types of PV modules are generally thin flat sheets, which for some types of backings may be flexible enough to conform to moderately curved mounting surfaces. Typically, the modules also have some kind of clear protective covering over the PV devices. Also the modules will have an electrical connector 4 which may be on a cable 3 as shown in FIGS. 1 and 2 or mounted directly to the module as shown in FIG. 3. The invention is intended to provide a module to power and/or charge an electrical device, such as laptop computers, batteries, cellphones and tablets as well as other power applications such as automobiles or electric vehicle batteries. The intent of the invention is to provide such a power module that can be affixed to a device or a surface, but also be removable and re-affixable to another device or surface at the user's discretion. This allows one power module to be used with a multitude of user devices or surfaces in a serial fashion, thus allowing a user to use the module on the device or surface currently in use and move the module to another device or surface when desired.

In the invention, the backing side of the module opposite the photovoltaic device side is covered at least in part with a semi-adhesive configured for the intended use of the invention. Therefore the semi-adhesive has to be chosen to have the following properties:

1. Adequate adhesive strength to fix an application suitable PV module to a device or surface well enough to stay fixed for the normal intended use of the PV module.
2. Adhere the module in such a way that it can be removed by hand and reaffixed in a manner consistent with 1 above for at least a few cycles without damaging the device or surface, or PV module. A variety of embodiments consistent with the above requirements are discussed below.

The preferred semi-adhesive is of a chemical type that may be sprayed, rolled or coated on in a manner known in the art. There are a wide variety of semi-adhesive materials that can be used to semi-permanently attach a PV module to a surface and allow the PV module to be lifted away from the surface without damage to the module or surface and support adhering the module to other surfaces multiple times. These include but are not limited to semi-adhesive glues or adhesives that can be applied to the PV backing or the surface to which the PV module will be attached. The semi-adhesive may be in the form of a spray, liquid, powder, tape, or double sided tape. The PV module and backing can be attached semi-permanently to a wide variety of surfaces, including but not limited to, metals, wood materials, plastics, fabrics, rock, painted surfaces, bare surfaces, polymers or any type of solid, rigid or flexible surface. The semi-adhesive may be added to the PV module at the time of module manufacture, and may also include a removable cover sheet to protect the semi-adhesive when not in use. The semi-adhesive may cover the entire back surface of the module, or may cover selected areas, chosen to aid in the degree of adherence, orientation and positioning of the module when attaching to the surface. Semi-adhesive may also be applied to the electrical cable 3 to help secure the cable to the mounting surface. The semi-adhesive may be of a type that is heat activated, either to increase or decrease the adhesiveness. It may also be of a type that may be re-applied, such as re-spraying, between uses.

Because modern PV modules are often quite thin and flexible, when affixed with a semi-adhesive, they conform to the surface and may be difficult to remove. Thus the invention also includes a lifting element 2. In a preferred embodiment, the lifting element is a tab extending out from an edge or side of the module. The tab can be attached to a PV module at the time of PV module manufacture, or at a later time. The tab can take numerous forms and shapes that extend from the PV module edge with the intention of facilitating easy detachment of the PV module from a surface. The tab may include cosmetic design features as well as ease of PV lifting design features. The tab shape extending beyond the PV module edge includes but is not limited to rounded shapes, square, rectangular, string, or irregular tab shapes. The common feature of the tabs is that they are connected to the edge, back or top of the PV module and facilitates a user's ability to pull or lift the PV device away from a surface with a minimum of time and effort without damage to the surface or PV module. The tab may also have a portion coated with a semi-adhesive for securing the tab to the mounting surface.

In another embodiment the lifting element 2 of the PV module edge is a beveled lifting edge as part of a module side that allows a finger or implement to pull the module up by applying pressure under the beveled edge. This embodiment is shown in FIG. 2.

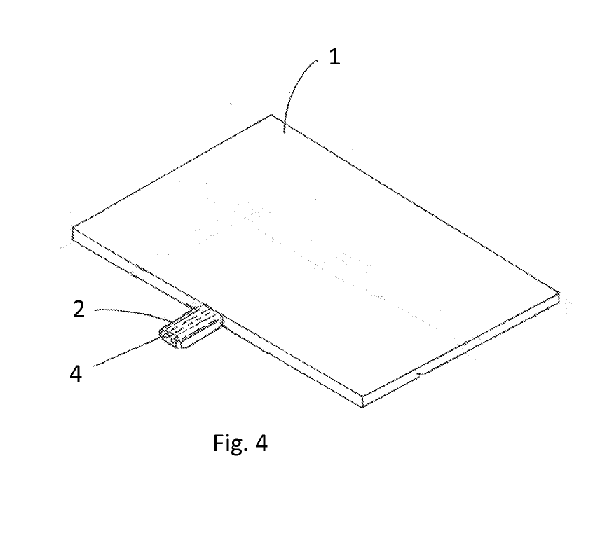

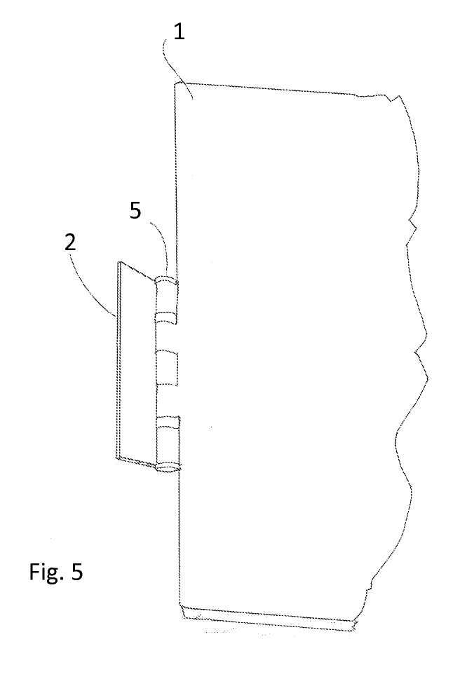

FIG. 4 shows an embodiment where the lifting element 2 and the electrical connector 4 are combined into one unit.

FIG. 5 shows another embodiment of the tab lifting element 2 where the tab 2 attached to the module 1 by a rotating hinge 5 allowing the tab to rotate flat against a surface or up away from the surface providing easy access for lifting the module up from a surface.

As a specific non-limiting example, the invention in a particular embodiment as applied to a solar powered laptop computer charger is discussed. A thin flexible gallium-arsenide PV module on a size scale of approximately 5 inches square is adequate to charge most laptops. The PV module backside may be all or partially covered with a semi-adhesive. Certain suitable semi-adhesives are known in the art as “repositionable adhesives” of which an exemplary suitable repositionable adhesive is 3M 9425 HT double sided tape. The tape permanent adhesive side (also known as high tack side) is applied to the module backing. The other removable tack tape side has a protective film. The lifting tab may also have the tape applied to it in a similar fashion. The film may be removed from the PV module and the module attached to the laptop cover, causing both the PV module and tab to remain attached to the surface during use or movement. The removable tack side of the tape is easily adequate to keep such a module attached to the laptop in normal use as the module conforms tightly to the mounting surface. The module is easily removable with a lifting tab to create separation and can be removed and re-attached multiple times over a period of up to a year or more. The PV module electrical output contact is then connected to the receiving electrical connection port, lead, or connector. The PV module generates electricity while exposed to a light source which may be outdoors or indoors. To remove the PV module at a later time from the surface, the PV electrical connector is unplugged, and the PV tab is gripped and the PV module is pulled away from the surface. Thus in this working example a PV module of a suitable type with an exemplary semi-adhesive, the module conforms tightly to the laptop cover and will remain in place for normal use for an indefinite time period. Removing the module and re-affixing to the same or another laptop can be done multiple times while maintaining adequate adhesion.

Other embodiments within the scope of the invention are possible. The PV backing may be of a type periodically recharged with a sticky surface adherence material in order to maintain a desired level of stickiness or to change the adhesive properties of the PV material depending on the intended use of the PV or properties of the surface to which it is attached. In another embodiment the semi-adhesive is applied to the surface and a tabbed PV is attached to that surface. In another embodiment a permanent adhesive is applied to the PV module backing or surface to which it will be attached. The permanent adhesive can be applied at any time the PV module is to be attached to a surface and after any number of module surface attachments and detachments. In another embodiment the tab is designed to be removed, torn-off or cut away from the PV module prior to or after attachment to a surface. This facilitates more PV options for permanent or temporary attachment and provides a smaller profile for the PV module when the PV module is intended to be applied permanently to a surface and there is no need to retain the tab.

The combination of the tab lifting element with non-chemical semi-adhesives such as Velcro type or magnets also provides benefits not found in existing PV modules.

The foregoing description of the embodiments of the present invention has shown, described and pointed out the fundamental novel features of the invention. It will be understood that various omissions, substitutions, and changes in the form of the detail of the systems and methods as illustrated as well as the uses thereof, may be made by those skilled in the art, without departing from the spirit of the invention. Consequently, the scope of the invention should not be limited to the foregoing discussions, but should be defined by appended claims.

I claim:

1. A detachable, repositionable photovoltaic module comprising:
a photovoltaic module body consisting of one or more photovoltaic cells on a first surface in an active region,
a chemical semi-adhesive disposed on at least a portion of a second surface opposite the photovoltaic surface side, wherein the semi-adhesive is suitable for two or more positioning, removing and re-positioning operations of the module to a mounting surface,
an electrical connector, and
at least one lifting element for removing operations.

2. The module of claim 1 wherein the lifting element is a tab attached to the module and extending from at least one edge or side of the module.

3. The module of claim 2 wherein the tab also has semi-adhesive on one at least a portion of its structure for removably securing the tab to the mounting surface.

4. The module of claim 2 wherein the tab and the electrical connection are combined into one element.

5. The module of claim 2 wherein the tab is hinged and rotatable from a flat position adjacent the mounting surface to a raised pulling position.

6. The module of claim 1 wherein the lifting element comprises a region of the module, sized and shaped for providing purchase for removing operations.

7. The module of claim 6 wherein the lifting element includes one or more of a beveled or raised edge or an extension of the module suitable for providing purchase for removing operations.

8. The module of claim 1 wherein the semi-adhesive on the opposite second surface and the semi-adhesive on the lifting element have differing semi-adhesive properties.

9. The module of claim 1 wherein the semi-adhesive includes one or more of a spray, liquid, powder, or double sided tape.

10. The module of claim 1 wherein the semi-adhesive is covered by a removable cover sheet when the module is not attached to a mounting surface.

11. The module of claim 1 wherein the semi-adhesive is renewable and may be at least one of re-applied or recharged between uses.

12. The module of claim 1 wherein the semi-adhesive requires a mating element applied to the mounting surface.

13. The module of claim 1 wherein the semi-adhesive is at least one of heat activated or de-activated.

14. A repositionable photovoltaic module comprising:
a photovoltaic module body consisting of one or more photovoltaic cells on a first surface in an active region,
Velcro adhesive disposed on at least a portion of a second surface opposite the photovoltaic surface side, for two or more positioning, removing and repositioning operations of the module to a mounting surface,
an electrical connector, and
a tab flexibly attached to the module and extending from at least one edge or side of the module.

15. A repositionable photovoltaic module comprising:
a photovoltaic module body consisting of one or more photovoltaic cells on a first surface in an active region,
Magnet(s) disposed on at least a portion of a second surface opposite the photovoltaic surface side, for two or more positioning, removing and re-positioning operations of the module to a mounting surface,
an electrical connector, and
a tab flexibly attached to the module and extending from at least one edge or side of the module.
